(19) United States
(12) Patent Application Publication
(10) Pub. No.: US 2012/0273781 A1
(43) Pub. Date: Nov. 1, 2012

(54) Device and Method For RF Characterization of Nanostructures and High Impedance Devices

(76) Inventors: Peter J. Burke, Irvine, CA (US); Steffen McKernan, San Clemente, CA (US); Dawei Wang, Irvine, CA (US); Zhen Yu, Irvine, CA (US)

(21) Appl. No.: 12/020,989

(22) Filed: Jan. 28, 2008

Related U.S. Application Data
(60) Provisional application No. 60/887,309, filed on Jan. 30, 2007.

(51) Int. Cl. H01L 21/66; H01L 23/58

(52) U.S. Cl. 257/48; 438/17; 257/E23.002; 257/E21.531

(57) ABSTRACT

A method and device are provided for the RF characterization of nanostructures and high impedance devices. A two-terminal electronic nanostructure device is fabricated by dividing a length of a nanostructure into a plurality of shorter, identical nanostructures using a plurality of finger electrodes electrically connected in parallel. The nanostructure may include a single walled carbon nanotube subdivided into shorter identical copies of a metallic nanotube segment by situating multiple finger electrodes along the length of the single walled carbon nanotube. Each of the subdivided shorter nanotube segments are connected in parallel. This arrangement allows for close impedance matching to radio frequency (RF) systems, and serves as an important technique in understanding and characterizing metallic (and even semiconducting) nanotubes at RF and microwave frequencies.

### TECHNICAL FIELD

This disclosure relates generally to the field of nanotube devices and, more particularly, to a low impedance nanostructure device capable of allowing RF characterization.

### BACKGROUND

The microwave (GHz) electrical properties of metallic nanotubes are important for both technology, as interconnects, and science, as basic studies of quantum transport in one-dimensional (1d) systems. For certain technological applications, especially interconnects, it can be useful to possess an experimentally verified RF circuit model for an individual metallic nanotube. Once verified, such a model could be used with confidence to build up more sophisticated models of many nanotubes configured in parallel at various bias voltages. The testing of such experimental models to date has been hampered by the low on current (˜10 μA) and high impedance (˜10 kΩ) of a single nanotube segment. Absolute measurements of the microwave conductance of such high impedance devices over a broad range of frequencies is difficult, and existing impedance matching techniques only work over a narrow range of frequencies.

One possible solution to addressing these absolute measurement problems is to measure many nanotubes in parallel to allow for low impedance devices for compatibility with microwave systems, which typically have source and load impedances of 50Ω. However, because of possible heterogeneous distribution of chiralities and diameters of the different nanotubes, each nanotube is likely to have slightly different electrical properties. Thus, absolute measurements of individual nanotube properties are not achieved using such a methodology, such that at best ensemble properties of the group of nanotubes are measured. Another possible solution is to use self-calibrating techniques and heroic efforts on RF calibrations, as some of the present inventors recently have done on one individual SWNT segment. However, such studies are both tedious and can have large ranges of error. For example, in one recent study by the present inventors, while relative changes of 1 μS in the microwave conductance (precision) were able to be resolved, the absolute value of G was only known to within 20 μS (accuracy). To date, measurements of the GHz properties of metallic single walled nanotubes have been a challenge.

### SUMMARY

According to a feature of the disclosure, a method is provided for the RF characterization of nanostructures and high impedance devices. In one or more embodiments, a technique is disclosed to fabricate a two-terminal electronic nanostructure device by dividing a length of a nanostructure into a plurality of shorter, identical sub-nanostructures using a plurality of finger electrodes electrically connected in parallel. In one or more embodiments, one longer (˜1 mm) single walled carbon nanotube is subdivided into shorter identical copies of a metallic nanotube segment by situating multiple finger electrodes along the length of the single walled carbon nanotube. Each of the subdivided shorter nanotube segments are connected in parallel. In one or more embodiments, this arrangement allows for close impedance matching to radio frequency (RF) systems, and serves as an important technique in understanding and characterizing metallic (and even semiconducting) nanotubes at RF and microwave frequencies.

In one or more embodiments, an overall resistance of 600 ohms for the nanostructure device can be achieved, thereby making the nanostructure device suitable for RF characterization. In one or more embodiments, multiple nanostructure devices can be made from a single nanotube where each of the nanostructure devices possesses virtually identical electrical characteristics at both low and high bias, at dc and ac (e.g., 100 MHz).

### DRAWINGS

The above-mentioned features and objects of the present disclosure will become more apparent with reference to the following description taken in conjunction with the accompanying drawings wherein like reference numerals denote like elements and in which:

FIG. 1 is an operational flow diagram for forming an electronic nanostructure device in accordance with one or more embodiments of the present disclosure.

FIG. 2 is an enlarged, schematic layout of a nanostructure device in accordance with one or more embodiments of the present disclosure.

FIG. 3 is an SEM image of a long single walled nanotube (SWNT) with multiple source/drain finger contacts in accordance with one or more embodiments of the present disclosure.

FIG. 4A is an exemplary schematic layout of two nanostructure devices formed from a single SWNT in accordance with one or more embodiments of the present disclosure.

FIG. 4B is a graphical representation of the current-voltage characteristics for two nanostructure devices formed from a single SWNT in accordance with one or more embodiments of the present disclosure.

FIG. 4C is an enlarged schematic view of a portion of the nanostructure devices illustrated in FIG. 4A.

FIG. 4D is a graphical representation of the V/I plots of the nanostructure devices illustrated in FIGS. 4A and 4B.

FIG. 5 is a graphical representation of measured S₁₁ scattering matrix values for two nanostructure devices formed from a single SWNT and a control device with no nanotube in accordance with one or more embodiments of the present disclosure.

### DETAILED DESCRIPTION

In one or more embodiments, the present disclosure is directed to a method for the RF characterization of nanostructures and high impedance devices. In the following description, numerous embodiments are set forth in order to provide a thorough understanding of the invention. It will be apparent, however, to one skilled in the art, that these and other embodiments may be practiced without these specific details. In other instances, well-known features have not been described in detail in order not to obscure the invention.

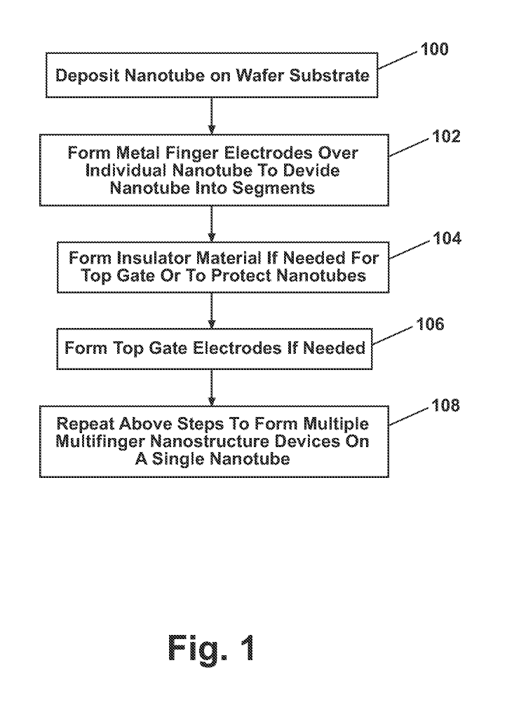

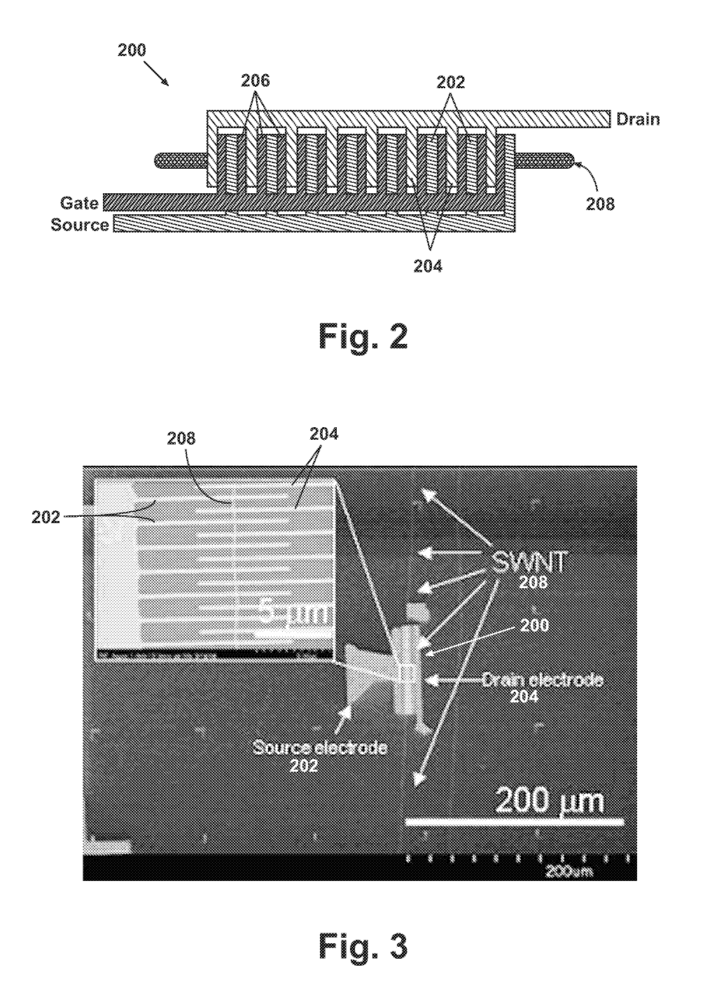

Referring now to the operational flow diagram of FIG. 1, in accordance with one or more embodiments, at least one individual single walled nanotube (SWNT) (e.g., a carbon nanotube or the like) is synthesized via chemical vapor deposition on a substrate in step 100 according to any carbon nanotube (CNT) recipes known to those skilled in the art. In one or more embodiments, the SWNT is deposited on an oxidized, high resistivity, p-doped Si wafer (e.g., ρ>10 kΩ-cm) having a dielectric layer formed thereon (e.g., a 400-500 nm SiO₂ layer). In step 102, multiple metal finger electrodes (source, drain, and gate finger electrodes) are formed on a segment of an individual SWNT using electron-beam lithography and metal evaporation a 10-nm Pd/10 nm Au bilayer. The electrode pattern contacting the SWNT segment is arranged in a “finger” geometry, as illustrated in FIG. 2. Each segment contains a nanostructure device 200 comprising a plurality of source finger electrodes 202, drain finger electrodes 204 and gate finger electrodes 206 formed on a SWNT 208.

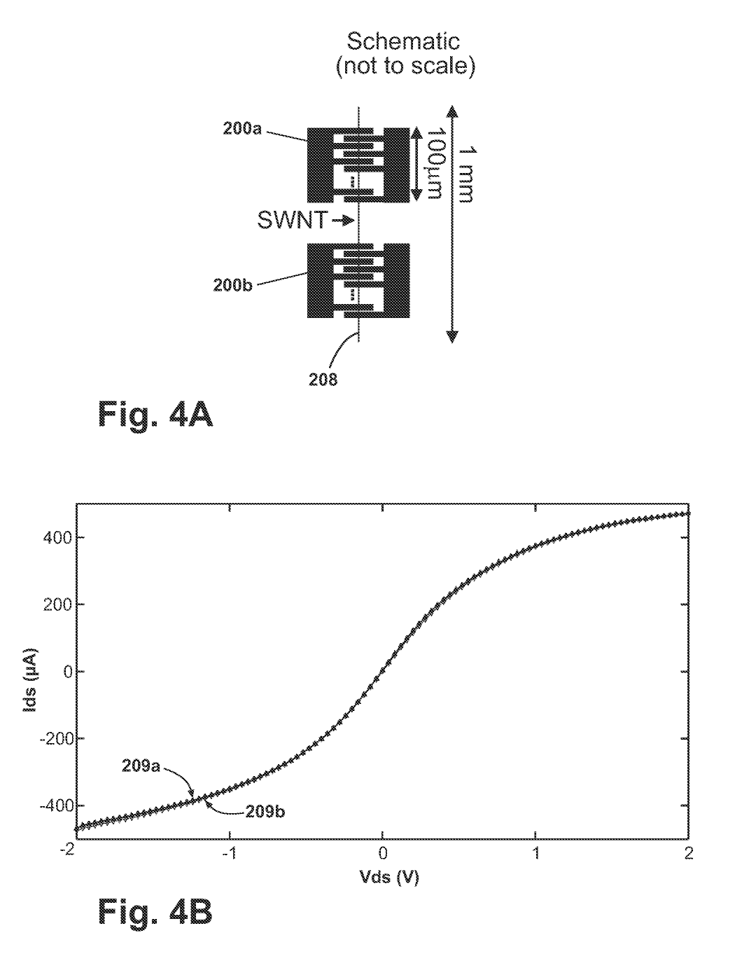

In one or more embodiments, this finger geometry allows for a plurality of source and drain electrode contacts 202 and 204 (e.g., 50 source and 50 drain electrode contacts) to be formed in each nanostructure device 200. Since current flows in both directions from each electrode contact 202/204, this allows for numerous nanotube segments to be combined and measured (e.g., a total of 100 nanotube segments for 50 source and 50 drain electrode contacts 202/204 in each nanostructure device 200), where the spacing between the electrode contacts 202 and 204 along the SWNT 208 is approximately 1 μm. Referring now to FIG. 3, an SEM image of one embodiment of such a nanostructure device 200 having a long SWNT 208 with multiple source/drain finger electrode contacts 202/204 and its layout are shown. Larger coplanar waveguide structures were also written (not shown in FIG. 3) for compatibility with a commercial RF probe station.

Referring back to FIG. 1, an insulator material (not shown) is formed over the components in step 104, and a metal gate electrode is formed over the insulator material in step 106 (e.g., an evaporated Au top-gate). Steps 104 and 106 are optionally performed to form a three-terminal nanostructure device 200; however, steps 104 and 106 may alternatively not be performed in order to form a two-terminal nanostructure device 200. In step 108, steps 102 through 106 are repeated in order to form at least one additional multi-finger nanostructure device 200 on the SWNT 208. In this manner, multiple multi-finger nanostructure devices 200 are formed on different segments of a single SWNT 208. It is understood that any of the steps in steps 102 through 108 can be combined or performed together such that the multiple multi-finger nanostructure devices 200 can be formed at the same time rather than in succession to each other. In this manner, a plurality of shorter, substantially identical sub-nanostructure devices 200 can be formed from a single nanostructure (e.g., an individual length of a SWNT 208).

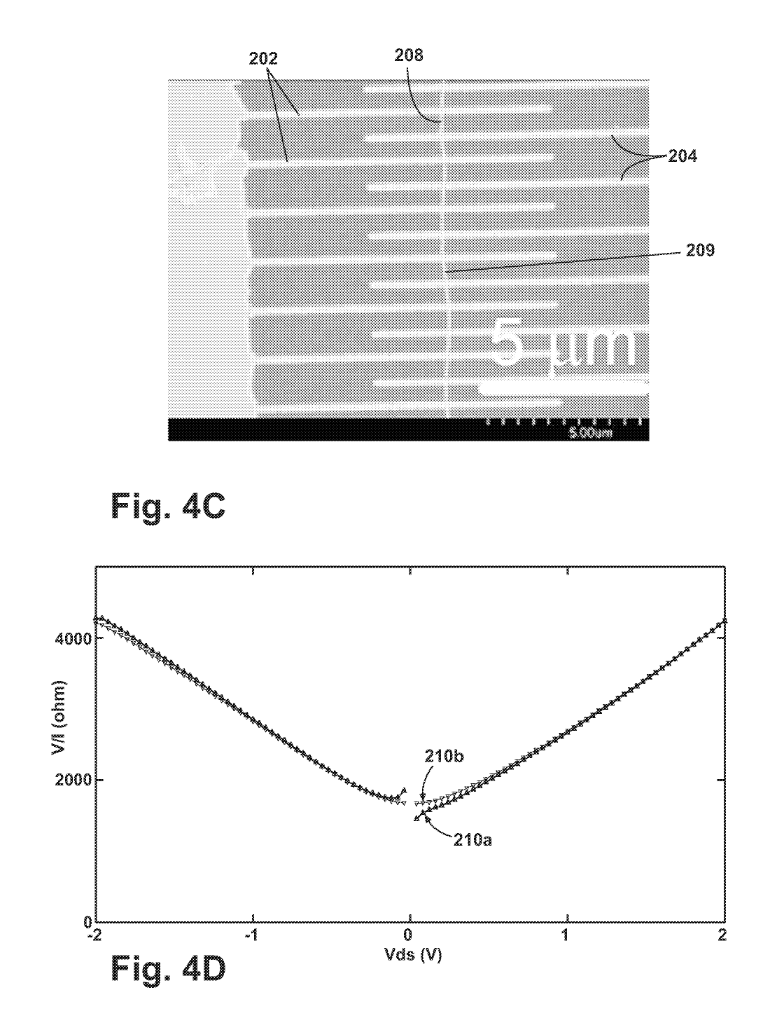

In one experimental embodiment, two RF compatible devices were fabricated on a single nanotube 208 on one wafer. The nanotube 208 was determined to be metallic due to the absence of conductance change with substrate bias. As embodied in FIG. 4B, a plot is shown of the I-V curves for the two separate, exemplary multi-finger devices 200a and 200b illustrated in FIG. 4A, where both multi-finger devices 200a and 200b were formed on the same nanotube 208. Prior studies on long individual SWNTs have shown that the (n,m) index can remain constant along the length of the nanotube. Thus, each of the nanostructure devices 200a and 200b formed on SWNT 208 should have similar or identical electrical properties. These results are confirmed in the I-V curves illustrated in FIG. 4B, as the respective I-V curves 209a and 209b for both separate nanostructure devices 200a and 200b are virtually identical and substantially indistinguishable in the plots shown in FIG. 4B. This clearly demonstrates that nanostructure devices 200 having identical properties can be fabricated on different portions of a single nanotube 208. In one or more embodiments, each separate nanostructure device 200 is a set of numerous (e.g., 100) finger electrodes arranged over an individual nanotube 208. While two such nanostructure devices 200a and 200b were fabricated for the data shown in FIG. 4B, it is understood that any number of a plurality of such nanostructure devices can be formed on each individual nanotube 208. Further, it is understood that each nanostructure device 200 can include any number of a plurality of finger electrodes. The nanostructure devices 200a and 200b associated with the embodiments of FIGS. 4A and 4B dissipate 1 mW of dc power while the low bias resistance is 1.8 kΩ, indicating resistance of 180 kΩ per segment 209 of nanotube 208 bounded by the individual fingers of the source and drain finger electrode contacts 202 in the nanostructure device 200, as illustrated in FIG. 4C.

It is well-established that in metallic SWNTs that are sufficiently long compared to the high field mean free path (of order 10 nm), each SWNT saturates at a current of around 25 μA. In order to further characterize these nanostructure devices 200a and 200b associated with the embodiments of FIGS. 4A and 4B, in one or more embodiments the value of V/I was plotted as shown in FIG. 4D. This illustrates that (over almost the entire range of applied voltage) the absolute resistance (V/I) can be described by a simple function V/I=R₀+|V|/I₀, where R₀ and I₀ are constants. From the slope of the linear part of the R-V curve, I₀=7 μA is found per segment 209 of nanotube 208, and between 10 and 25 μA per nanotube 208 for the other devices, in qualitative agreement expected findings for such devices.

In one or more embodiments, in order to measure the dynamical impedance at microwave frequencies, a commercially available microwave probe (suitable for calibration with a commercially available open/short/load calibration standard) can be connected to the nanostructure devices 200 to allow for transition from coax to lithographically fabricated on chip electrodes. A microwave network analyzer can then be used to measure the calibrated (complex) reflection coefficient S₁₁(ω)≡V_{reflected}/V_{incident}, where V_{incident} is the amplitude of the incident microwave signal on the coax, and similarly for V_{reflected}. This is related to the load impedance Z(ω) by the usual reflection formula:

S₁₁=[Z(ω)−50Ω]/[Z(ω)+50Ω]. (1)

In one or more embodiments, the results are independent of the power used (e.g., independent for the power levels of approximately 3 μW used for one or more embodiments described herein). A commercially available calibration wafer on ceramic with known standards can be used to perform an open/short/load (OSL) calibration. In one experimental study, nanostructure devices 200 formed on doped Si were measured, wherein doped Si absorbs some microwave power due to fringing RF fields. For an ideal open circuit, S₁₁=0 dB, from equation (1) above, since Z=infinity. In experimental studies performed by the present inventors on Si, S₁₁ was found to deviate from 0 dB in control experiments with the same multi-finger electrode arrangement as the nanostructure device 200 but with no nanotube present. This is due to the parasitic absorption from the conducting substrate, as well as the parasitic capacitance of the finger electrodes, and was not accounted for in this calibration.

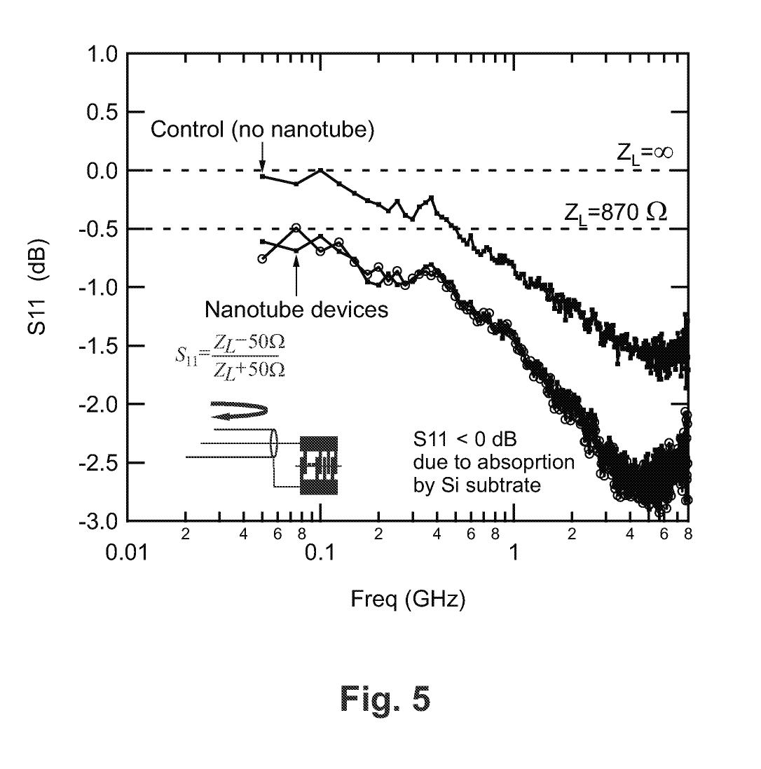

Referring now to FIG. 5, a graphical plot is provided for the value of S₁₁ measured for the same two nanostructure devices 200a and 200b utilized for the data shown in FIGS. 4A-4C and also for a control structure formed on Si without any nanotubes. Both nanostructure devices 200a and 200b absorb some power (S11<0 dB) due to the lossy Si substrate but the effect of the SWNT 208 is readily apparent. The control structure absorbs some microwave power (i.e., S₁₁ is not equal to 0 dB), as expected. Further experimentation can be performed to calibrated out this effect. The nanostructure devices 200a and 200b clearly function differently over the entire frequency range from the open structure, indicating that the nanotube intrinsic properties are clearly being observed, separate from the control structure. At low frequencies, the value of S₁₁ tends to about −0.5 dB where the parasitic absorption of the Si substrate is becoming vanishingly small. This indicates that the measured value of S₁₁ in the low frequency (100 MHz) limit can be taken as the intrinsic value. In one embodiment, based on equation (1), this would correspond to a resistance of 870Ω, which is close to the measured dc resistance of 1800Ω. In prior research performed by the present inventors (based on a single metallic nanotube segment), it was necessary to resolve S₁₁ to 0.0005 dB to see the nanotube signal. The results shown in FIG. 5 clearly demonstrates the power of the present method, as both nanostructure devices 200a and 200b have identical RF characteristics.

As can be seen from the above, the present disclosure describes a technique to probe nanotube device properties at GHz frequencies without the need for impedance matching circuits or heroic calibration efforts. While the technique has been demonstrated for metallic nanotubes, it is broadly applicable to any nanotube device, provided multiple identical copies of each nanotube device can be manufactured.

While the system and method have been described in terms of what are presently considered to be specific embodiments, the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

1. A method is provided for the RF characterization of nanostructures, comprising:
forming a length of a nanostructure into a plurality of shorter sub-nanostructures,
electrically connecting the divided sub-nanostructures in parallel, and
probing the sub-nanostructures in order to characterize the properties of the sub-nanostructures at certain frequencies.

2. The method of claim 1, further comprising characterizing the sub-nanostructures at radio frequencies.

3. The method of claim 1, further comprising characterizing the sub-nanostructures at microwave frequencies.

4. The method of claim 1, further comprising characterizing the sub-nanostructures without the use of an impedance matching circuit.

5. The method of claim 1, further comprising forming each of the sub-nanostructures to include a plurality of finger electrodes electrically connected in parallel.

6. The method of claim 1, further comprising forming each of the sub-nanostructures to possess substantially identical characteristics.

7. The method of claim 1, wherein the nanostructure comprises an individual single walled carbon nanotube.

8. The method of claim 1, further comprising electrically connecting the divided sub-nanostructures in parallel to collectively possess a net low impedance.

9. The method of claim 1, further comprising electrically connecting the divided sub-nanostructures in parallel to collectively possess an overall resistance of 600 ohms suitable for RF characterization.

10. The method of claim 1, further comprising using the characterization to develop circuit models for nanodevices.

11. A low impedance nanostructure device capable of allowing RF characterization, comprising:
a length of an individual nanotube divided into a plurality of electrically contacted segments,
each of the electrically contacted segments including a plurality of finger electrodes as contact electrodes, and
each of the electrically contacted segments connected together in parallel.

12. The low impedance nanostructure device of claim 10, wherein the nanotube is a metallic single walled carbon nanotube.

13. The low impedance nanostructure device of claim 11, wherein the device can be characterized at radio frequencies.

14. The low impedance nanostructure device of claim 11, wherein the device can be characterized at microwave frequencies.

15. The low impedance nanostructure device of claim 11, wherein the device can be characterized without the use of an impedance matching circuit.

16. The low impedance nanostructure device of claim 11, wherein the plurality of finger electrodes from each of the electrically contacted segments are connected to respective finger electrodes from the other electrically contacted segments.

17. The low impedance nanostructure device of claim 11, wherein each of the electrically contacted segments possess substantially identical characteristics.

18. The low impedance nanostructure device of claim 11, wherein the device possesses a net low impedance.

19. The low impedance nanostructure device of claim 11, wherein the device possesses an overall resistance of 600 ohms suitable for RF characterization.
